(19) United States
(12) Patent Application Publication
(10) Pub. No.: US 2025/0087414 A1
(43) Pub. Date: Mar. 13, 2025

(54) ELECTRONIC COMPONENT

(71) Applicant: TDK Corporation, Tokyo (JP)

(72) Inventor: Longfei YI, Tokyo (JP)

(73) Assignee: TDK Corporation, Tokyo (JP)

(21) Appl. No.: 18/782,186

(22) Filed: Jul. 24, 2024

(30) Foreign Application Priority Data
Sep. 12, 2023 (JP) 2023-147721

(51) Int. Cl. H01F 27/40; H01F 27/28; H01F 27/29

(52) U.S. Cl. CPC H01F 27/40; H01F 27/2804; H01F 27/29; H01F 2027/2809

(57) ABSTRACT

An electronic component includes an element body and a plurality of inductors disposed in the element body. The plurality of inductors include an inductor unit, an inductor unit, and an inductor unit. Each of the inductor unit, the inductor unit, and the inductor unit has two conductors extending in one direction and a connection conductor connecting respective one ends of the two conductors in the one direction. Respective axial directions of the inductor unit, the inductor unit, and the inductor unit do not overlap each other and are parallel to each other when viewed from the one direction.

### CROSS-REFERENCE TO RELATED APPLICATION

This application claims priority to Japanese Patent Application No. 2023-147721, filed on Sep. 12, 2023, which is incorporated herein by reference in its entirety.

### TECHNICAL FIELD

The present disclosure relates to an electronic component.

### BACKGROUND

Patent Literature 1 (Japanese Unexamined Patent Publication No. 2016-508356) discloses an electronic component (diplexer) including a substrate having a plurality of through-substrate vias, a first plurality of traces on a first surface of the substrate coupled to the plurality of through-substrate vias, a second plurality of traces on a second surface of the substrate opposite to the first surface, coupled to opposite ends of the plurality of through-substrate vias, the plurality of through-substrate vias and the traces operating as 3D inductors, and a capacitor supported by the substrate.

### SUMMARY

An object of one aspect of the present disclosure is to provide an electronic component capable of effectively using a space in an element body and obtaining desired characteristics.

(1) An electronic component according to an aspect of the present disclosure includes an element body; and a plurality of inductors disposed in the element body, in which the plurality of inductors include a first inductor, a second inductor, and a third inductor, each of the first inductor, the second inductor, and the third inductor has two conductors extending in one direction, and a connection conductor connecting respective one ends of the two conductors in the one direction, and respective axial directions of the first inductor, the second inductor, and the third inductor do not overlap each other and are parallel to each other when viewed from the one direction.

In the electronic component according to the one aspect of the present disclosure, the respective axial directions of the first inductor, the second inductor, and the third inductor do not overlap each other and are parallel to each other when viewed from the one direction. As described above, in the electronic component, the inductors can be efficiently disposed by disposing the plurality of inductors with axes shifted in the element body. Therefore, in the electronic component, a space in the element body can be effectively used (space efficiency in the element body can be enhanced). In the electronic component, the plurality of inductors include at least the first inductor, the second inductor, and the third inductor. In this configuration, inductance of the inductor can be adjusted by making the respective axial directions not overlap each other and parallel to each other when viewed from the one direction. Therefore, in the electronic component, desired characteristics can be obtained.

(2) In the electronic component of (1) above, an orientation of a magnetic field generated in each of the first inductor and the second inductor and an orientation of a magnetic field generated in the third inductor are opposite to each other. In this configuration, in an element including the first inductor and the second inductor and an element including the third inductor, it is possible to suppress an influence on characteristics of the elements.

(3) In the electronic component of (1) or (2) above, in the first inductor, a first opening may be formed by the two conductors and the connection conductor, in the second inductor, a second opening may be formed by the two conductors and the connection conductor, in the third inductor, a third opening may be formed by the two conductors and the connection conductor, and at least parts of the first opening and the second opening may overlap each other and the first opening and the third opening may not overlap each other when viewed from the axial direction. In this configuration, inductance can be suitably adjusted.

(4) In the electronic component of (1) or (2) above, in the first inductor, a first opening may be formed by the two conductors and the connection conductor, in the second inductor, a second opening may be formed by the two conductors and the connection conductor, in the third inductor, a third opening may be formed by the two conductors and the connection conductor, the first opening may be smaller than the second opening, and at least parts of the first opening and the second opening may overlap each other and the first opening and the third opening may not overlap each other when viewed from the axial direction. In a case where an element including the first inductor and the second inductor and an element including the third inductor have different characteristics, when the first opening of the first inductor is smaller than the second opening of the second inductor, the first inductor may be affected more by the third inductor than the second inductor. Therefore, by preventing the first opening and the third opening from overlapping, the first inductor can be prevented from being affected by the third inductor. As a result, in the electronic component, inductance adjustment and the like can be performed, and desired characteristics can be obtained.

(5) In the electronic component of any one of (1) to (4) above, each of the plurality of inductors may have two conductors extending in the one direction, and a connection conductor connecting respective one ends of the two conductors in the one direction. In this configuration, the magnetic field of the inductor can be controlled, and the inductor can be efficiently disposed.

(6) In the electronic component of any one of (1) to (5) above, the first inductor, the second inductor, and the third inductor may be arranged side by side in the axial direction. In this configuration, the inductor can be efficiently disposed in the element body. In addition, it is possible to suppress magnetic coupling in the first inductor, the second inductor, and the third inductor.

(7) In the electronic component of any one of (1) to (5) above, the plurality of inductors may include a fourth inductor and a fifth inductor, each of the fourth inductor and the fifth inductor may have two conductors extending in the one direction, and a connection conductor connecting respective one ends of the two conductors in the one direction, respective axial directions of the fourth inductor and the fifth inductor may not overlap each other and may be parallel to each other when viewed from the one direction, and the respective axial directions of the first inductor, the second inductor, and the third inductor may be orthogonal to the respective axial directions of the fourth inductor and the fifth inductor when viewed from the one direction. In this configuration, it is possible to efficiently dispose the inductors by disposing the plurality of inductors with the axes shifted in the element body. Therefore, in the electronic component, a space in the element body can be effectively used (space efficiency in the element body can be enhanced). In the electronic component, the plurality of inductors include the fourth inductor and the fifth inductor. In this configuration, inductance of the inductor can be adjusted by making the respective axial directions not overlap each other and parallel to each other when viewed from the one direction. Therefore, in the electronic component, desired characteristics can be obtained.

According to one aspect of the present disclosure, a space in an element body can be effectively used, and desired characteristics can be obtained.

### BRIEF DESCRIPTION OF THE DRAWINGS

FIG. 1 is an equivalent circuit diagram of an electronic component according to an embodiment;

FIGS. 2A and 2B are perspective diagrams of the electronic component according to the embodiment;

FIG. 3 is a transparent perspective diagram of the electronic component illustrated in FIGS. 2A and 2B;

FIG. 4 is an exploded perspective diagram of the electronic component;

FIG. 5 is a diagram of the electronic component as viewed from a main surface side; and

FIG. 6 is a diagram of an inductor unit as viewed from an axial direction.

### DETAILED DESCRIPTION

Hereinafter, a preferred embodiment of the present disclosure will be described in detail with reference to the accompanying drawings. Note that the same or corresponding elements in the description of the drawings are denoted by the same reference signs, and redundant description is omitted.

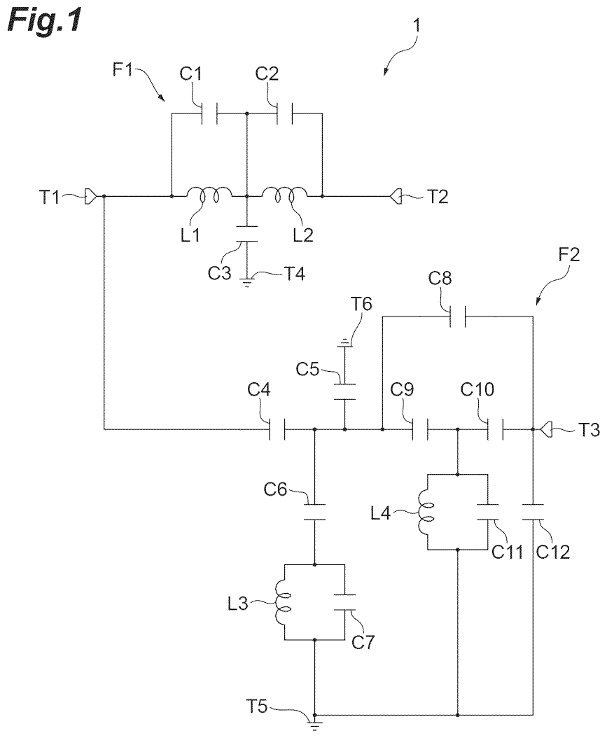

FIG. 1 is an equivalent circuit diagram of an electronic component according to an embodiment. The electronic component 1 includes an input terminal T1 to which a signal is input, a first output terminal T2 to which a signal is output, a second output terminal T3 to which a signal is output, a ground terminal T4, a ground terminal T5, a ground terminal T6, a first filter F1 provided between the input terminal T1 and the first output terminal T2, and a second filter F2 provided between the input terminal T1 and the second output terminal T3. The electronic component 1 is, for example, a diplexer.

The first filter F1 is, for example, a low-pass filter. The first filter F1 selectively allows a first signal to pass therethrough out of the first signal having a frequency within a first frequency band and a second signal having a frequency within a second frequency band that is a frequency band higher than the first frequency band. The first filter F1 has an inductor L1, an inductor L2, a capacitor C1, a capacitor C2, and a capacitor C3. The inductor L1 and the capacitor C1, and the inductor L2 and the capacitor C2 constitute a resonator (resonance circuit), respectively.

The second filter F2 is, for example, a high-pass filter. The second filter F2 selectively allows the second signal to pass therethrough. The second filter F2 has an inductor L3, an inductor L4, a capacitor C4, a capacitor C5, a capacitor C6, a capacitor C7, a capacitor C8, a capacitor C9, a capacitor C10, a capacitor C11, and a capacitor C12. The inductor L3 and the capacitor C8 constitute a resonator. The inductor L4 and the capacitor C11 constitute a resonator.

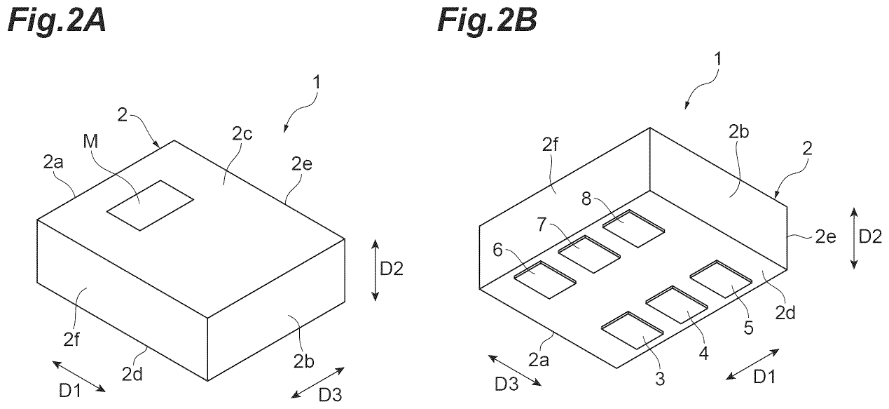

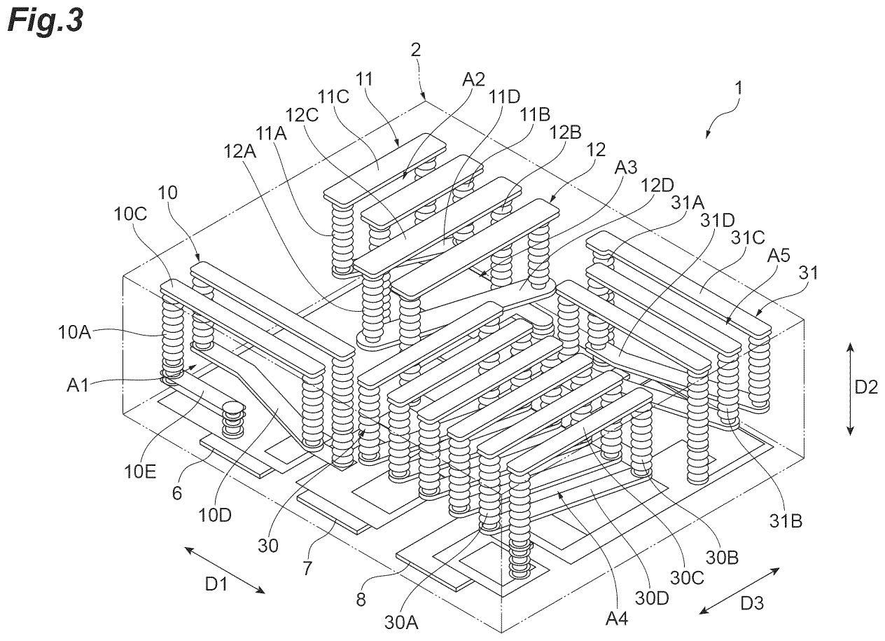

A configuration of the electronic component according to the embodiment will be described with reference to FIGS. 2A, 2B, and 3. FIGS. 2A and 2B are perspective diagrams of the electronic component. FIG. 3 is a transparent perspective diagram of the electronic component illustrated in FIGS. 2A and 2B. As illustrated in FIGS. 2A, 2B, and 3, the electronic component 1 includes an element body 2, a first terminal electrode 3, a second terminal electrode 4, and a third terminal electrode 5. In FIG. 3, the element body 2 is indicated by a two-dot chain line.

The element body 2 has a rectangular parallelepiped shape. The rectangular parallelepiped shape includes a shape of a rectangular parallelepiped in which corner parts and ridge line parts are chamfered, or a shape of a rectangular parallelepiped in which corner parts and ridge line parts are rounded. The element body 2 has, as outer surfaces, a pair of end surfaces 2a and 2b, a pair of main surfaces 2c and 2d, and a pair of side surfaces 2e and 2f. The end surfaces 2a and 2b face each other. The main surfaces 2c and 2d face each other. The side surfaces 2e and 2f face each other. Hereinafter, a facing direction of the end surfaces 2a and 2b is referred to as a first direction D1, a facing direction of the main surfaces 2c and 2d is referred to as a second direction (one direction) D2, and a facing direction of the side surfaces 2e and 2f is referred to as a third direction D3. The first direction D1, the second direction D2, and the third direction D3 are substantially orthogonal to each other.

The end surfaces 2a and 2b extend in the second direction D2 so as to be connected to the main surfaces 2c and 2d. The end surfaces 2a and 2b also extend in the third direction D3 so as to be connected to the side surfaces 2e and 2f. The main surfaces 2c and 2d extend in the first direction D1 so as to be connected to the end surfaces 2a and 2b. The main surfaces 2c and 2d also extend in the third direction D3 so as to be connected to the side surfaces 2e and 2f. The side surfaces 2e and 2f extend in the first direction D1 so as to be connected to the end surfaces 2a and 2b. The side surfaces 2e and 2f also extend in the second direction D2 so as to be connected to the main surfaces 2c and 2d.

The main surface 2d is a mounting surface, for example, a surface facing another electronic device (for example, circuit substrate or multilayer electronic component) when the electronic component 1 is implemented on the another electronic device (not illustrated). The end surfaces 2a and 2b are surfaces continuous from the mounting surface (that is, the main surface 2d). A mark M is provided on the main surface 2c. The mark M indicates an orientation and a direction of the electronic component 1. Note that the mark M may not be provided.

A length of the element body 2 in the first direction D1 is longer than a length of the element body 2 in the second direction D2 and a length of the element body 2 in the third direction D3. The length of the element body 2 in the second direction D2 is shorter than the length of the element body 2 in the third direction D3. That is, in the present embodiment, the end surfaces 2a and 2b, the main surfaces 2c and 2d, and the side surfaces 2e and 2f have a rectangular shape. The length of the element body 2 in the second direction D2 may be equal to the length of the element body 2 in the third direction D3, or may be longer than the length of the element body 2 in the third direction D3.

It should be noted that “equal” in the present embodiment may mean not only “equal” but also a value including a slight difference, a manufacturing error, or the like in a preset range. For example, when a plurality of values are included within a range of ±5% of an average value of the plurality of values, the plurality of values are defined to be equal.

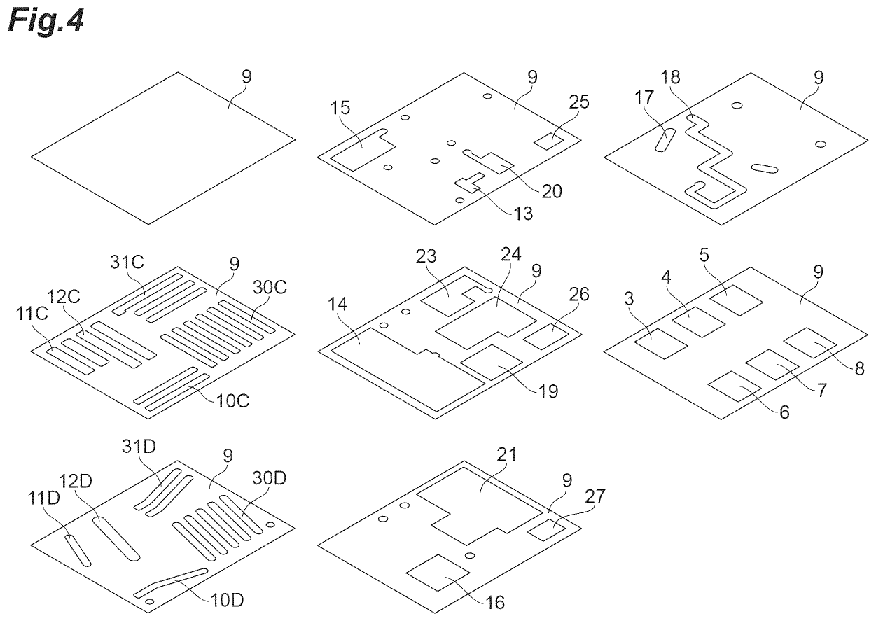

The element body 2 is formed by laminating a plurality of insulator layers 9 (see FIG. 4) in the second direction D2. That is, a laminating direction of the element body 2 is the second direction D2. In the actual element body 2, the plurality of insulator layers 9 may be integrated to such an extent that boundaries between the layers cannot be visually recognized, or may be integrated such that boundaries between the layers can be visually recognized.

The insulator layer 9 is formed by using, for example, a sintered body of a ceramic green sheet containing a dielectric material. The dielectric material includes, for example, at least one selected from a BaTiO₃ based material, a Ba(Ti, Zr)O₃ based material, a (Ba, Ca)TiO₃ based material, a glass material, or an alumina material.

Each of the first terminal electrode 3, the second terminal electrode 4, the third terminal electrode 5, the fourth terminal electrode 6, the fifth terminal electrode 7, and the sixth terminal electrode 8 is provided on the element body 2. Each of the first terminal electrode 3, the second terminal electrode 4, the third terminal electrode 5, the fourth terminal electrode 6, the fifth terminal electrode 7, and the sixth terminal electrode 8 is disposed on the main surface 2d of the element body 2. The first terminal electrode 3, the second terminal electrode 4, and the third terminal electrode 5 are disposed at positions closer to the side surface 2e. The fourth terminal electrode 6, the fifth terminal electrode 7, and the sixth terminal electrode 8 are disposed at positions closer to the side surface 2f.

The first terminal electrode 3 is located on the end surface 2a side, and the third terminal electrode 5 is located on the end surface 2b side. The second terminal electrode 4 is located between the first terminal electrode 3 and the third terminal electrode 5 in the first direction D1. The fourth terminal electrode 6 is located on the end surface 2a side, and the sixth terminal electrode 8 is located on the end surface 2b side. The fifth terminal electrode 7 is located between the fourth terminal electrode 6 and the sixth terminal electrode 8 in the first direction D1. The first terminal electrode 3 and the fourth terminal electrode 6 are disposed to face each other in the third direction D3. The second terminal electrode 4 and the fifth terminal electrode 7 are disposed to face each other in the third direction D3. The third terminal electrode 5 and the sixth terminal electrode 8 are disposed to face each other in the third direction D3.

Each of the first terminal electrode 3, the second terminal electrode 4, the third terminal electrode 5, the fourth terminal electrode 6, the fifth terminal electrode 7, and the sixth terminal electrode 8 has a rectangular shape (quadrilateral shape). Each of the first terminal electrode 3, the second terminal electrode 4, the third terminal electrode 5, the fourth terminal electrode 6, the fifth terminal electrode 7, and the sixth terminal electrode 8 is disposed such that each side extends along the first direction D1 or the third direction D3. The first terminal electrode 3, the second terminal electrode 4, the third terminal electrode 5, the fourth terminal electrode 6, the fifth terminal electrode 7, and the sixth terminal electrode 8 protrude from the main surface 2d. That is, in the present embodiment, respective surfaces of the first terminal electrode 3, the second terminal electrode 4, the third terminal electrode 5, the fourth terminal electrode 6, the fifth terminal electrode 7, and the sixth terminal electrode 8 are not flush with the main surface 2d. The first terminal electrode 3, the second terminal electrode 4, the third terminal electrode 5, the fourth terminal electrode 6, the fifth terminal electrode 7, and the sixth terminal electrode 8 are made of a conductive material (for example, Cu).

A plating layer (not illustrated) containing, for example, Ni, Sn, Au, or the like may be provided in each of the first terminal electrode 3, the second terminal electrode 4, the third terminal electrode 5, the fourth terminal electrode 6, the fifth terminal electrode 7, and the sixth terminal electrode 8 by electrolytic plating or electroless plating. The plating layer may include, for example, an Ni plating film containing Ni and covering the first terminal electrode 3, the second terminal electrode 4, the third terminal electrode 5, the fourth terminal electrode 6, the fifth terminal electrode 7, and the sixth terminal electrode 8, and an Au plating film containing Au and covering the Ni plating film.

The fifth terminal electrode 7 constitutes the input terminal T1. The first terminal electrode 3 constitutes the first output terminal T2. The third terminal electrode 5 constitutes the second output terminal T3. The second terminal electrode 4 constitutes the ground terminal T5. The sixth terminal electrode 8 constitutes the ground terminal T6.

Next, the configurations of the first filter F1 and the second filter F2 will be described in detail. In the electronic component 1, the first filter F1 and the second filter F2 are disposed in the element body 2.

As illustrated in FIG. 3, the inductor L1 (see FIG. 1) of the first filter F1 (see FIG. 1) is composed of an inductor unit (fourth inductor) 10. The inductor L2 (see FIG. 1) is composed of an inductor unit (first inductor) 11 and an inductor unit (second inductor) 12. The capacitor C1 (see FIG. 1) is composed of a capacitor conductor 13 and a capacitor conductor 14. As illustrated in FIG. 4, the capacitor C2 (see FIG. 1) is composed of the capacitor conductor 14 and a capacitor conductor 15. The capacitor C3 (see FIG. 1) is composed of the capacitor conductor 14 and a capacitor conductor 16. The capacitor conductor 15 is electrically connected to the first terminal electrode 3 via a connection conductor 17. The capacitor conductor 16 is electrically connected to the second terminal electrode 4 via a connection conductor 18.

The inductor unit 10 includes a first conductor 10A, a second conductor 10B, a first inductor conductor (connection conductor) 10C, and a second inductor conductor 10D. In the present embodiment, the inductor unit 10 includes two first conductors 10A, two second conductors 10B, and two first inductor conductors 10C.

The first conductor 10A extends along the second direction D2 (one direction). The first conductor 10A can be composed of a plurality of via conductors. The second conductor 10B extends along the second direction D2. The second conductor 10B can be composed of a plurality of via conductors. The first conductor 10A and the first conductor 10A are disposed at a predetermined interval in the third direction D3. The second conductor 10B and the second conductor 10B are disposed at a predetermined interval in the third direction D3. The first conductor 10A and the second conductor 10B are disposed at a predetermined interval in the first direction D1.

The first inductor conductor 10C electrically connects the first conductor 10A and the second conductor 10B. The first inductor conductor 10C has a substantially rectangular shape (long shape). The first inductor conductor 10C is disposed over one end (end on the main surface 2c side) of the first conductor 10A in the second direction D2 and one end (end on the main surface 2c side) of the second conductor 10B in the second direction D2. The first inductor conductor 10C is stretched between the first conductor 10A and the second conductor 10B. The first inductor conductor 10C is disposed such that a longitudinal direction of the first inductor conductor 10C is along the first direction D1. That is, the first inductor conductor 10C extends in the first direction D1. The first inductor conductor 10C may be composed of one conductor or may be composed of a plurality of (for example, two) conductors.

One first conductor 10A, one second conductor 10B, and one first inductor conductor 10C constitute a channel-shaped (substantially U-shaped or substantially C-shaped) inductor. In the present embodiment, the inductor unit 10 includes the two inductors.

The second inductor conductor 10D electrically connects the first conductor 10A and the second conductor 10B. The second inductor conductor 10D electrically connects the above two inductors. The second inductor conductor 10D connects the other end (end on the main surface 2d side) of the first conductor 10A in the second direction D2 and the other end (end on the main surface 2d side) of the second conductor 10B in the second direction D2. The second inductor conductor 10D may be composed of one conductor or may be composed of a plurality of (for example, two) conductors.

One end of the inductor unit 10 is connected to the capacitor conductor 14 via a connection conductor 10E. The other end of the inductor unit 10 is connected to a capacitor conductor 19.

The inductor unit 11 includes a first conductor 11A, a second conductor 11B, a first inductor conductor (connection conductor) 11C, and a second inductor conductor 11D. In the present embodiment, the inductor unit 11 includes two first conductors 11A, two second conductors 11B, and two first inductor conductors 11C.

The first conductor 11A extends along the second direction D2. The first conductor 11A can be composed of a plurality of via conductors. The second conductor 11B extends along the second direction D2. The second conductor 11B can be composed of a plurality of via conductors. The first conductor 11A and the first conductor 11A are disposed at a predetermined interval in the first direction D1. The second conductor 11B and the second conductor 11B are disposed at a predetermined interval in the first direction D1. The first conductor 11A and the second conductor 11B are disposed at a predetermined interval in the third direction D3.

The first inductor conductor 11C electrically connects the first conductor 11A and the second conductor 11B. The first inductor conductor 11C has a substantially rectangular shape (long shape). The first inductor conductor 11C is disposed over one end (end on the main surface 2c side) of the first conductor 11A in the second direction D2 and one end (end on the main surface 2c side) of the second conductor 11B in the second direction D2. The first inductor conductor 11C is stretched between the first conductor 11A and the second conductor 11B. The first inductor conductor 11C is disposed such that a longitudinal direction of the first inductor conductor 11C is along the third direction D3. That is, the first inductor conductor 11C extends in the third direction D3. The extending direction of the first inductor conductor 11C is orthogonal to the extending direction of the first inductor conductor 10C. The first inductor conductor 11C may be composed of one conductor or may be composed of a plurality of (for example, two) conductors.

One first conductor 11A, one second conductor 11B, and one first inductor conductor 11C constitute a channel-shaped (substantially U-shaped or substantially C-shaped) inductor. In the present embodiment, the inductor unit 11 includes the two inductors.

The second inductor conductor 11D electrically connects the first conductor 11A and the second conductor 11B. The second inductor conductor 11D electrically connects the above two inductors. The second inductor conductor 11D connects the other end (end on the main surface 2d side) of the first conductor 11A in the second direction D2 and the other end (end on the main surface 2d side) of the second conductor 11B in the second direction D2. The second inductor conductor 11D may be composed of one conductor or may be composed of a plurality of (for example, two) conductors.

One end of the inductor unit 11 is connected to the capacitor conductor 14. The other end of the inductor unit 11 is connected to the capacitor conductor 15.

The inductor unit 12 includes a first conductor 12A, a second conductor 12B, a first inductor conductor (connection conductor) 12C, and a second inductor conductor 12D. In the present embodiment, the inductor unit 12 includes two first conductors 12A, two second conductors 12B, and two first inductor conductors 12C.

The first conductor 12A extends along the second direction D2. The first conductor 12A can be composed of a plurality of via conductors. The second conductor 12B extends along the second direction D2. The second conductor 12B can be composed of a plurality of via conductors. The first conductor 12A and the first conductor 12A are disposed at a predetermined interval in the first direction D1. The second conductor 12B and the second conductor 12B are disposed at a predetermined interval in the first direction D1. The first conductor 12A and the second conductor 12B are disposed at a predetermined interval in the third direction D3.

The first inductor conductor 12C electrically connects the first conductor 12A and the second conductor 12B. The first inductor conductor 12C has a substantially rectangular shape (long shape). The first inductor conductor 12C is disposed over one end (end on the main surface 2c side) of the first conductor 12A in the second direction D2 and one end (end on the main surface 2c side) of the second conductor 12B in the second direction D2. The first inductor conductor 12C is stretched between the first conductor 12A and the second conductor 12B. The first inductor conductor 12C is disposed such that a longitudinal direction of the first inductor conductor 12C is along the third direction D3. That is, the first inductor conductor 12C extends in the third direction D3. The extending direction of the first inductor conductor 12C is orthogonal to the extending direction of the first inductor conductor 10C, and is parallel to the extending direction of the first inductor conductor 11C. The first inductor conductor 12C may be composed of one conductor or may be composed of a plurality of (for example, two) conductors.

One first conductor 12A, one second conductor 12B, and one first inductor conductor 12C constitute a channel-shaped (substantially U-shaped or substantially C-shaped) inductor. In the present embodiment, the inductor unit 12 includes the two inductors.

The second inductor conductor 12D electrically connects the first conductor 12A and the second conductor 12B. The second inductor conductor 12D electrically connects the above inductors. The second inductor conductor 12D connects the other end (end on the main surface 2d side) of the first conductor 12A in the second direction D2 and the other end (end on the main surface 2d side) of the second conductor 12B in the second direction D2. The second inductor conductor 12D may be composed of one conductor or may be composed of a plurality of (for example, two) conductors.

One end of the inductor unit 12 is connected to the capacitor conductor 14. The other end of the inductor unit 12 is connected to the capacitor conductor 15.

As illustrated in FIG. 3, the inductor L3 (see FIG. 1) of the second filter F2 (see FIG. 1) is composed of an inductor unit (third inductor) 30. The inductor L4 (see FIG. 1) is composed of an inductor unit (fifth inductor) 31. The capacitor C4 (see FIG. 1) is composed of the capacitor conductor 19 and a capacitor conductor 20. As illustrated in FIG. 4, the capacitor C5 (see FIG. 1) is composed of a capacitor conductor 24 and a ground conductor of a mounting substrate. The capacitor C6 (see FIG. 1) is composed of a capacitor conductor 25 and a capacitor conductor 26.

The capacitor C7 (see FIG. 1) is composed of its own parasitic capacitance (capacitance) of the inductor unit 30. The capacitor C8 (see FIG. 1) is composed of the capacitor conductor 24 and a capacitor conductor 21. The capacitor C9 (see FIG. 1) is configured by (planar) coupling of the capacitor conductor 24 and a capacitor conductor 23. The capacitor C10 (see FIG. 1) is composed of the capacitor conductor 23 and the capacitor conductor 21. The capacitor C11 (see FIG. 1) is composed of its own parasitic capacitance (capacitance) of the inductor unit 31. The capacitor C12 (see FIG. 1) is composed of the capacitor conductor 21 and the ground conductor of the mounting substrate.

The inductor unit 30 includes a first conductor 30A, a second conductor 30B, a first inductor conductor (connection conductor) 30C, and a second inductor conductor 30D. In the present embodiment, the inductor unit 30 includes six first conductors 30A, six second conductors 30B, six first inductor conductors 30C, and five second inductor conductors 30D.

The first conductor 30A extends along the second direction D2. The first conductor 30A can be composed of a plurality of via conductors. The second conductor 30B extends along the second direction D2. The second conductor 30B can be composed of a plurality of via conductors. The first conductor 30A and the first conductor 30A are disposed at a predetermined interval in the first direction D1. The second conductor 30B and the second conductor 30B are disposed at a predetermined interval in the first direction D1. The first conductor 30A and the second conductor 30B are disposed at a predetermined interval in the third direction D3.

The first inductor conductor 30C electrically connects the first conductor 30A and the second conductor 30B. The first inductor conductor 30C has a substantially rectangular shape (long shape). The first inductor conductor 30C is disposed over one end (end on the main surface 2c side) of the first conductor 30A in the second direction D2 and one end (end on the main surface 2c side) of the second conductor 30B in the second direction D2. The first inductor conductor 30C is stretched between the first conductor 30A and the second conductor 30B. The first inductor conductor 30C is disposed such that a longitudinal direction of the first inductor conductor 30C is along the third direction D3. That is, the first inductor conductor 30C extends in the third direction D3. The first inductor conductor 30C may be composed of one conductor or may be composed of a plurality of (for example, two) conductors.

One first conductor 30A, one second conductor 30B, and one first inductor conductor 30C constitute a channel-shaped (substantially U-shaped or substantially C-shaped) inductor. In the present embodiment, the inductor unit 30 includes the six inductors.

The second inductor conductor 30D electrically connects the first conductor 30A and the second conductor 30B. The second inductor conductor 30D electrically connects the above two inductors. The second inductor conductor 30D connects the other end (end on the main surface 2d side) of the first conductor 30A in the second direction D2 and the other end (end on the main surface 2d side) of the second conductor 30B in the second direction D2. The second inductor conductor 30D may be composed of one conductor or may be composed of a plurality of (for example, two) conductors.

One end of the inductor unit 30 is connected to the capacitor conductor 24. The other end of the inductor unit 12 is connected to the capacitor conductor 25.

The inductor unit 31 includes a first conductor 31A, a second conductor 31B, a first inductor conductor (connection conductor) 31C, and a second inductor conductor 31D. In the present embodiment, the inductor unit 31 includes two first conductors 31A, two second conductors 31B, two first inductor conductors 31C, and two second inductor conductors 31D.

The first conductor 31A extends along the second direction D2. The first conductor 31A can be composed of a plurality of via conductors. The second conductor 31B extends along the second direction D2. The second conductor 31B can be composed of a plurality of via conductors. The first conductor 31A and the first conductor 31A are disposed at a predetermined interval in the third direction D3. The second conductor 31B and the second conductor 31B are disposed at a predetermined interval in the third direction D3. The first conductor 31A and the second conductor 31B are disposed at a predetermined interval in the first direction D1.

The first inductor conductor 31C electrically connects the first conductor 31A and the second conductor 31B. The first inductor conductor 31C has a substantially rectangular shape (long shape). The first inductor conductor 31C is disposed over one end (end on the main surface 2c side) of the first conductor 31A in the second direction D2 and one end (end on the main surface 2c side) of the second conductor 31B in the second direction D2. The first inductor conductor 31C is stretched between the first conductor 31A and the second conductor 31B. The first inductor conductor 31C is disposed such that a longitudinal direction of the first inductor conductor 31C is along the first direction D1. That is, the first inductor conductor 31C extends in the first direction D1. The extending direction of the first inductor conductor 31C is orthogonal to the extending direction of the first inductor conductor 30C. The first inductor conductor 31C may be composed of one conductor or may be composed of a plurality of (for example, two) conductors.

One first conductor 31A, one second conductor 31B, and one first inductor conductor 31C constitute a channel-shaped (substantially U-shaped or substantially C-shaped) inductor. In the present embodiment, the inductor unit 31 includes the three inductors.

The second inductor conductor 12D electrically connects the first conductor 12A and the second conductor 12B. The second inductor conductor 12D electrically connects the above two inductors. The second inductor conductor 12D connects the other end (end on the main surface 2d side) of the first conductor 12A in the second direction D2 and the other end (end on the main surface 2d side) of the second conductor 12B in the second direction D2. The second inductor conductor 12D may be composed of one conductor or may be composed of a plurality of (for example, two) conductors.

One end of the inductor unit 31 is connected to the capacitor conductor 23. The other end of the inductor unit 12 is connected to the second terminal electrode 4.

In the present embodiment, as illustrated in FIG. 3, the inductor unit 10, the inductor unit 11, the inductor unit 12, the inductor unit 30, and the inductor unit 31 have the same height position on the main surface 2c side in the second direction D2. That is, the first inductor conductor 10C, the first inductor conductor 11C, the first inductor conductor 12C, the first inductor conductor 30C, and the first inductor conductor 31C are disposed at the same height position in the second direction D2.

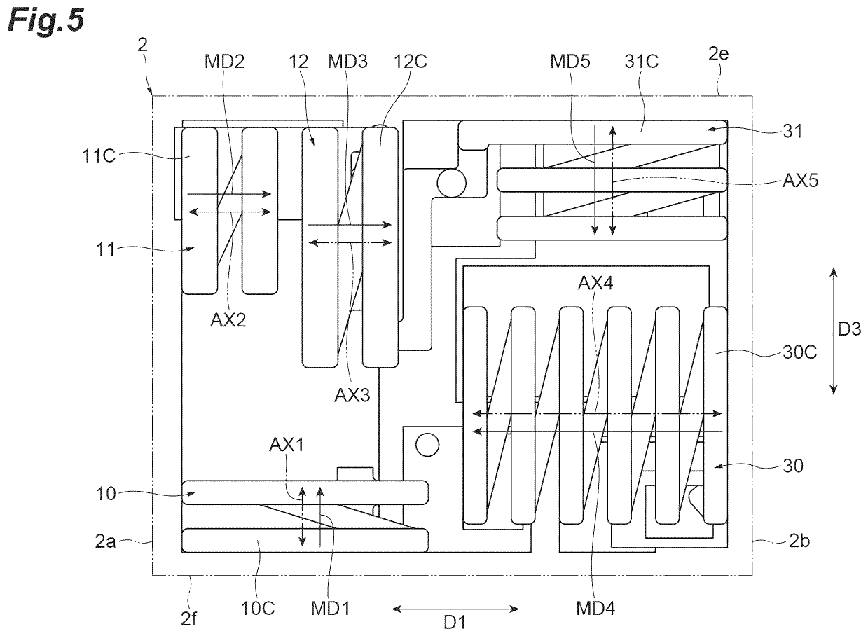

As illustrated in FIG. 5, the inductor unit 10, the inductor unit 11, and the inductor unit 12 are disposed at positions closer to the end surface 2a. The inductor unit 30 and the inductor unit 31 are disposed at positions closer to the end surface 2b.

The inductor unit 10, the inductor unit 11, and the inductor unit 12 are disposed at positions overlapping each other when viewed from the third direction D3. The inductor unit 30 and the inductor unit 31 are disposed at positions overlapping each other when viewed from the third direction D3. The inductor unit 11, the inductor unit 12, and the inductor unit 30 are arranged side by side in the first direction D1. The inductor unit 11, the inductor unit 12, and the inductor unit 30 are disposed at positions not overlapping each other when viewed from the third direction D3. The inductor unit 12 and the inductor unit 30 are disposed at positions partially overlapping each other as viewed from the first direction D1.

An opening A1 is formed in the inductor unit 10 by the first conductor 10A, the second conductor 10B, and the first inductor conductor 10C. A direction (axial direction) of an axis AX1 of the inductor unit 10 is the third direction D3. The axis means a central axis of an inductor configured by the first conductor 10A, the second conductor 10B, and the first inductor conductor 10C. The axis AX1 may be a center of the opening A1. A direction MD1 of a magnetic field generated in the inductor unit 10 is along the third direction D3. The direction MD1 of the magnetic field is a direction from the side surface 2f toward the side surface 2e of the element body 2. The direction of the axis AX1 and the direction MD1 of the magnetic field are the same direction.

An opening (first opening) A2 is formed in the inductor unit 11 by the first conductor 11A, the second conductor 11B, and the first inductor conductor 11C. A direction (axial direction) of an axis AX2 of the inductor unit 11 is the first direction D1. The axis AX2 may be a center of the opening A2. A direction MD2 of a magnetic field generated in the inductor unit 11 is along the first direction D1. The direction MD2 of the magnetic field is a direction from the end surface 2a toward the end surface 2b of the element body 2. The direction of the axis AX2 and the direction MD2 of the magnetic field are the same direction.

An opening (second opening) A3 is formed in the inductor unit 12 by the first conductor 12A, the second conductor 12B, and the first inductor conductor 12C. A direction (axial direction) of an axis AX3 of the inductor unit 12 is the first direction D1. The axis AX3 may be a center of the opening A3. A direction MD3 of a magnetic field generated in the inductor unit 12 is along the first direction D1. The direction MD3 of the magnetic field is a direction from the end surface 2a toward the end surface 2b of the element body 2. The direction of the axis AX3 and the direction MD3 of the magnetic field are the same direction.

An opening (third opening) A4 is formed in the inductor unit 30 by the first conductor 30A, the second conductor 30B, and the first inductor conductor 30C. A direction (axial direction) of an axis AX4 of the inductor unit 30 is the first direction D1. The axis AX4 may be a center of the opening A4. A direction MD4 of a magnetic field generated in the inductor unit 30 is along the first direction D1. The direction MD4 of the magnetic field is a direction from the end surface 2b to the end surface 2a of the element body 2. The direction of the axis AX4 and the direction MD4 of the magnetic field are the same direction.

An opening A5 is formed in the inductor unit 31 by the first conductor 31A, the second conductor 31B, and the first inductor conductor 31C. A direction (axial direction) of an axis AX5 of the inductor unit 31 is the third direction D3. The axis AX5 can be a center of the opening A5. A direction MD5 of a magnetic field generated in the inductor unit 31 is along the third direction D3. The direction MD5 of the magnetic field is a direction from the side surface 2e to the side surface 2f of the element body 2. The direction of the axis AX5 and the direction MD5 of the magnetic field are the same direction.

The direction of the axis AX1 of the inductor unit 10 and the direction of the axis AX5 of the inductor unit 31 are the same direction (third direction D3). The direction of the axis AX1 of the inductor unit 10 and the axis AX5 of the inductor unit 31 are parallel to each other. The direction of the axis AX2 of the inductor unit 11, the direction of the axis AX3 of the inductor unit 12, and the direction of the axis AX3 of the inductor unit 12 are the same direction (first direction D1). The direction of the axis AX2 of the inductor unit 11, the direction of the axis AX3 of the inductor unit 12, and the direction of the axis AX3 of the inductor unit 12 are parallel to each other.

The direction of the axis AX1 of the inductor unit 10, the direction of the axis AX2 of the inductor unit 11, and the direction of the axis AX3 of the inductor unit 12 are orthogonal to each other. The direction of the axis AX4 of the inductor unit 30 and the axis AX5 of the inductor unit 31 are orthogonal to each other.

The direction MD1 of the magnetic field generated in the inductor unit 10 and the direction MD5 of the magnetic field generated in the inductor unit 31 are opposite to each other. The direction MD2 of the magnetic field generated in the inductor unit 11 and the direction MD3 of the magnetic field generated in the inductor unit 12 are the same direction. The direction MD2 of the magnetic field generated in the inductor unit 11 and the direction MD3 of the magnetic field generated in the inductor unit 12 are opposite to the direction MD4 of the magnetic field generated in the inductor unit 30. The direction MD1 of the magnetic field generated in the inductor unit 10 and the direction MD5 of the magnetic field generated in the inductor unit 31 are orthogonal to the direction MD2 of the magnetic field generated in the inductor unit 11, the direction MD3 of the magnetic field generated in the inductor unit 12, and the direction MD4 of the magnetic field generated in the inductor unit 30.

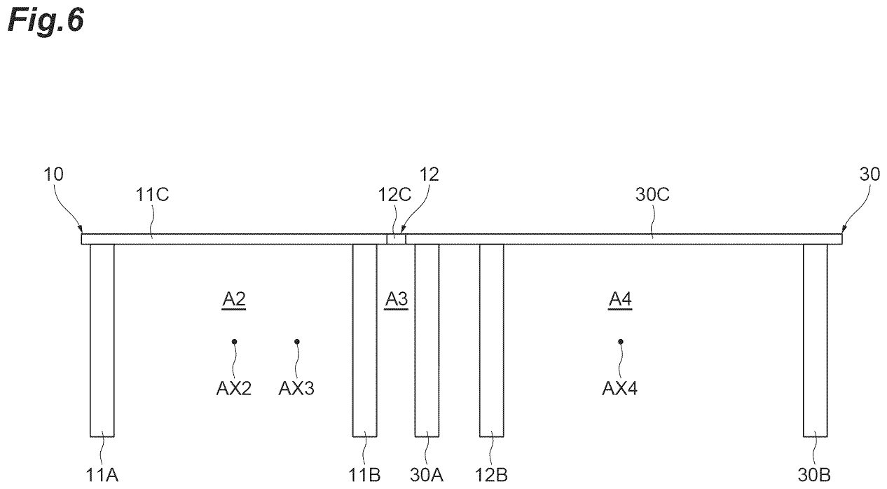

As illustrated in FIG. 6, the opening A2 of the inductor unit 11 is smaller than the opening A3 of the inductor unit 12 and the opening A4 of the inductor unit 30. The opening A3 of the inductor unit 12 may be smaller than the opening A4 of the inductor unit 30, may be the same as the opening A4 of the inductor unit 30, or may be larger than the opening A4 of the inductor unit 30.

When viewed from the first direction D1, the opening A2 of the inductor unit 11 overlaps the opening A3 of the inductor unit 12. When viewed from the first direction D1, a part of the opening A3 of the inductor unit 12 overlaps the opening A4 of the inductor unit 30. When viewed from the first direction D1, the opening A2 of the inductor unit 11 does not overlap the opening A4 of the inductor unit 30.

As described above, in the electronic component 1 according to the present embodiment, the directions of the axes AX2, AX3, and AX4 of each of the inductor unit 11, the inductor unit 12, and the inductor unit 30 do not overlap each other and are parallel to each other when viewed from the second direction D2. As described above, in the electronic component 1, the inductors can be efficiently disposed by disposing the plurality of inductors by shifting the axes AX2, AX3, and AX4 in the element body 2. Therefore, in the electronic component 1, a space in the element body 2 can be effectively used (space efficiency in the element body 2 can be enhanced). In the electronic component 1, the plurality of inductors include the inductor unit 11, the inductor unit 12, and the inductor unit 30. In this configuration, when the directions of each of the axes AX2, AX3, and AX4 do not overlap each other and are parallel to each other as viewed from the second direction D2, the inductances of the inductor unit 11, the inductor unit 12, and the inductor unit 30 can be adjusted. Therefore, in the electronic component 1, desired characteristics can be obtained.

In the electronic component 1 according to the present embodiment, an orientation of the magnetic field generated in each of the inductor unit 11 and the inductor unit 12 and an orientation of the magnetic field generated in the inductor unit 30 are opposite to each other. In this configuration, the first filter F1 (element) including the inductor unit 11 and the inductor unit 12 and the second filter F2 including the inductor unit 30 can be prevented from affecting the characteristics of the filters.

In the electronic component 1 according to the present embodiment, the opening A2 is formed by the first conductor 11A, the second conductor 11B, and the first inductor conductor 11C in the inductor unit 11, the opening A3 is formed by the first conductor 12A, the second conductor 12B, and the first inductor conductor 12C in the inductor unit 12, and the opening A4 is formed by the first conductor 30A, the second conductor 30B, and the first inductor conductor 30C in the inductor unit 30. In the electronic component 1, when viewed from the first direction D1 (axial direction), the opening A2 and the opening A3 overlap each other, and the opening A2 and the opening A4 do not overlap each other. In this configuration, inductance can be suitably adjusted.

In the electronic component 1 according to the present embodiment, the opening A2 of the inductor unit 11 is smaller than the opening A3 of the inductor unit 12. In the electronic component 1, when viewed from the first direction D1, the opening A2 and the opening A3 overlap each other, and the opening A2 and the opening A5 do not overlap each other. In a case where the first filter F1 including the inductor unit 11 and the inductor unit 12 and the second filter F2 including the inductor unit 30 have different characteristics, when the opening A2 of the inductor unit 11 is smaller than the opening A3 of the inductor unit 12, the inductor unit 11 may be more affected by the inductor unit 30 than the inductor unit 12. Therefore, by preventing the opening A2 and the opening A4 from overlapping, the inductor unit 11 can be prevented from being affected by the inductor unit 30. As a result, in the electronic component 1, inductance adjustment and the like can be performed, and desired characteristics can be obtained.

In the electronic component 1 according to the present embodiment, the inductor unit 11, the inductor unit 12, and the inductor unit 30 are arranged side by side in the direction of the axes AX2, AX3, and AX4. In this configuration, the inductors can be efficiently disposed in the element body 2. In addition, it is possible to suppress magnetic coupling in the inductor unit 11, the inductor unit 12, and the inductor unit 30.

In the electronic component 1 according to the present embodiment, the directions of the axes AX1 and AX5 of each of the inductor unit 10 and the inductor unit 31 do not overlap each other and are parallel to each other when viewed from the second direction D2. In the electronic component 1, as viewed from the second direction D2, the directions of the axes AX2, AX3, and AX4 of each of the inductor unit 11, the inductor unit 12, and the inductor unit 30 are orthogonal to the axes AX1 and AX5 of each of the inductor unit 10 and the inductor unit 31. In this configuration, it is possible to efficiently dispose the inductors by disposing the plurality of inductors with the axes shifted in the element body 2. Therefore, in the electronic component 1, a space in the element body 2 can be effectively used (space efficiency in the element body can be enhanced).

Although the embodiment of the present disclosure has been described in the foregoing, the present disclosure is not necessarily limited to the above-described embodiment, and various modifications can be made without departing from the gist thereof.

In the above embodiment, a mode in which the electronic component 1 includes the inductor unit 10, the inductor unit 11, the inductor unit 12, the inductor unit 30, and the inductor unit 31 has been described as an example. However, the electronic component 1 only needs to include at least the inductor unit 10, the inductor unit 11, and the inductor unit 12. The electronic component 1 may include six or more inductor units.

In each of the inductor unit 10, the inductor unit 11, the inductor unit 12, the inductor unit 30, and the inductor unit 31, the numbers and shapes of the first conductor, the second conductor, the first inductor conductor, and the second inductor conductor are not particularly limited, and may be appropriately set.

What is claimed is:

1. An electronic component comprising:
an element body; and
a plurality of inductors disposed in the element body, wherein
the plurality of inductors include a first inductor, a second inductor, and a third inductor,
each of the first inductor, the second inductor, and the third inductor has
two conductors extending in one direction, and
a connection conductor connecting respective one ends of the two conductors in the one direction, and
respective axial directions of the first inductor, the second inductor, and the third inductor do not overlap each other and are parallel to each other when viewed from the one direction.

2. The electronic component according to claim 1, wherein an orientation of a magnetic field generated in each of the first inductor and the second inductor and an orientation of a magnetic field generated in the third inductor are opposite to each other.

3. The electronic component according to claim 1, wherein
in the first inductor, a first opening is formed by the two conductors and the connection conductor,
in the second inductor, a second opening is formed by the two conductors and the connection conductor,
in the third inductor, a third opening is formed by the two conductors and the connection conductor, and
at least parts of the first opening and the second opening overlap each other and the first opening and the third opening do not overlap each other when viewed from the axial direction.

4. The electronic component according to claim 1, wherein
in the first inductor, a first opening is formed by the two conductors and the connection conductor,
in the second inductor, a second opening is formed by the two conductors and the connection conductor,
in the third inductor, a third opening is formed by the two conductors and the connection conductor,
the first opening is smaller than the second opening, and
at least parts of the first opening and the second opening overlap each other and the first opening and the third opening do not overlap each other when viewed from the axial direction.

5. The electronic component according to claim 1, wherein
each of the plurality of inductors has
two conductors extending in the one direction, and
a connection conductor connecting respective one ends of the two conductors in the one direction.

6. The electronic component according to claim 1, wherein the first inductor, the second inductor, and the third inductor are arranged side by side in the axial direction.

7. The electronic component according to claim 1, wherein
the plurality of inductors include a fourth inductor and a fifth inductor,
each of the fourth inductor and the fifth inductor has
two conductors extending in the one direction, and
a connection conductor connecting respective one ends of the two conductors in the one direction,
respective axial directions of the fourth inductor and the fifth inductor do not overlap each other and are parallel to each other when viewed from the one direction, and
the respective axial directions of the first inductor, the second inductor, and the third inductor are orthogonal to the respective axial directions of the fourth inductor and the fifth inductor when viewed from the one direction.
